(19) United States
(12) Patent Application Publication
(10) Pub. No.: US 2011/0156063 A1
(43) Pub. Date: Jun. 30, 2011

(54) ORGANIC LIGHT EMITTING DIODE (OLED) DISPLAY DEVICE

(75) Inventors: Chun-Liang Lin, Hsin-Chu (TW); Yao-An Mo, Hsin-Chu (TW); Chieh-Wei Chen, Hsin-Chu (TW)

(73) Assignee: AU OPTRONICS CORP., Hsinchu (TW)

(21) Appl. No.: 12/940,650

(22) Filed: Nov. 5, 2010

(30) Foreign Application Priority Data
Dec. 28, 2009 (TW) 098145320

(51) Int. Cl. H01L 51/52

(52) U.S. Cl. 257/88; 257/E51.022

(57) ABSTRACT

An exemplary OLED display device includes a substrate, a colored photo-resist layer and a white OLED arranged in that order. The white OLED includes a reflecting electrode, a transmitting electrode, and an organic white light emitting layer arranged between the reflecting electrode and the transmitting electrode for emitting a white light. The colored photo-resist layer at least includes first through third photo-resist regions, the first through third photo-resist regions contain red pigment particles, green pigment particles and blue pigment particles respectively for extracting red, green and blue light components from the white light. Moreover, the colored photo-resist layer has an expected haze value e.g., greater than 30 by at least utilizing the scattering of the red, green and blue pigment particles and/or mixing of scattering particles that are different from the red, green and blue pigment particles into the first through third photo-resist regions.

### BACKGROUND

1. Technical Field

The present invention relates generally to a display device and, particularly to an organic light emitting diode display device.

2. Description of the Related Art

Organic light emitting diode (OLED) display devices are becoming one of the new display devices of the next generation because of the advantages thereof such as light weight, thin thickness, high color saturation, high contrast ratio, and can be formed on flexible substrates. Currently, OLED full color display devices can be mainly divided/classified into a red-green-blue (RGB) light mixing type architecture and a white organic light emitting diodes in collocation with color filters type architecture according to different colorizing manners. In particular, in one aspect, the RGB light mixing type OLED display device generally employs a shadow mask to define the positions of red, green, and blue OLEDs, however would encounter the issues of low resolution and uneasily being scaled up; in another aspect, in regard to the white OLEDs in collocation with color filters type architecture, since the red, green, and blue sub-pixels thereof can be formed by a well-developed/mature photolithography process, thus can readily achieve better resolution and scaling up, but the disadvantage thereof is relatively low light output efficiency. Therefore, if wanting to employ the OLEDs for the application of large-sized display devices such as televisions, the white organic light emitting diodes with color filters type OLED display device is a feasible candidate, but what is needed is to improve the issue of low output efficiency.

### BRIEF SUMMARY

Accordingly, the present invention is directed to an OLED display device having an improved light output efficiency.

In particular, an embodiment of the present invention provides an OLED display device including a substrate, a colored photo-resist layer and a white OLED. The colored photo-resist layer is disposed on the substrate. The white OLED is disposed on the colored photo-resist layer. The white OLED includes a reflecting electrode, a transmitting electrode, and an organic white light emitting layer interposed between the reflecting electrode and the transmitting electrode and for emitting a white light. The colored photo-resist at least includes a first photo-resist region, a second photo-resist region and a third photo-resist region. The first photo-resist region, the second photo-resist region and the third photo-resist region respectively contain red pigment particles, green pigment particles and blue pigment particles therein for extracting/filtering red, green, blue light components from the white light. Moreover, the colored photo-resist layer has a desired haze value for example, greater than 30 by at least utilizing a scattering effect of the red pigment particles, the green pigment particles and the blue pigment particles and/or mixing of scattering particles that are different with the red pigment particles, the green pigment particles and the blue pigment particles into the first photo-resist region, the second photo-resist region and the third photo-resist region.

In another embodiment of the present invention, the colored photo-resist layer at least utilizes the scattering particles to obtain the desired haze value. A material of the scattering particles is selected from the group consisting of titanium oxide (TiOₓ), silicon oxide (SiO₂), magnesium oxide (MgO), zirconium oxide (ZrOₓ), tin oxide (SnO), beryllium oxide (BeO), zinc sulfide (ZnS), zinc selenide (ZnSe), and mixtures thereof. A grain size of the scattering particles is in the range of less than 1000 nanometers.

In yet another embodiment of the present invention, the colored photo-resist layer at least utilizes the scattering effect of the red pigment particles, the green pigment particles and the blue pigment particles to obtain the desired haze value. Grain sizes of the red pigment particles, the green pigment particles and the blue pigment particles are in the range of greater than 100 nanometers and less than 1000 nanometers.

In still another embodiment of the present invention, the transmitting electrode is an indium tin oxide (ITO) electrode.

Another embodiment of the present invention provides an OLED display device including a substrate, a colored photo-resist layer and a white light emitting component/member. The colored photo-resist layer is disposed on the substrate. The white light emitting member is disposed on the colored photo-resist layer. The white light emitting member includes a metal electrode, a transparent conductive layer, and a number of organic layers. The organic layer is for emitting a white light and interposed between the metal electrode and the transparent conductive layer. The colored photo-resist includes at least three photo-resist regions for respectively extracting light components of three different colors from the white light. At least some of the three photo-resist regions contains pigment particles therein. Moreover, the colored photo-resist layer has a decided haze value for example, greater than 30 by at least utilizing a scattering effect of the pigment particles and/or mixing of scattering particles, which having a refractive index different that of the pigment particles, into the photo-resist regions.

In above embodiments, the colored photo-resist layer uses the scattering effect of the scattering particles mixed into the colored photo-resist layer or at least partly increasing the grain sizes of the pigment particles in the colored photo-resist layer to obtain a desired scattering effect, so that the haze value of the colored photo-resist layer can achieve greater than 30. Accordingly, the OLED display device using the colored photo-resist layer can achieve a relatively higher light output efficiency.

Other aspects, details, and advantages of the present OLED display device are further described in detail accompanying with preferred embodiments and figures as follows.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic view showing a structure of an OLED display device in accordance with a first embodiment of the present invention.

FIG. 2 is a schematic principle view illustrating a definition of haze value in accordance with the first embodiment of the present invention.

FIG. 3 is a schematic view showing a structure of an OLED display device in accordance with a second embodiment of the present invention.

### DETAILED DESCRIPTION

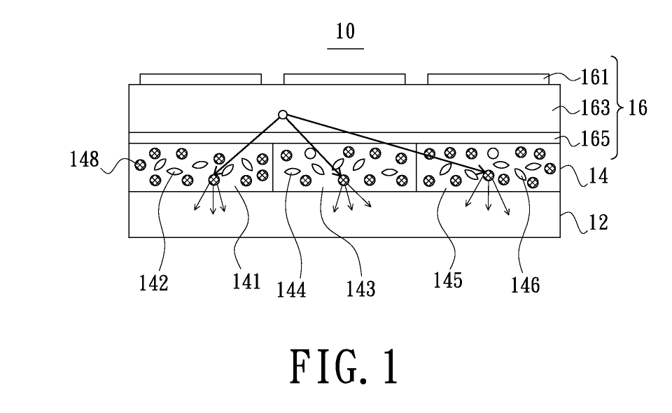

Referring to FIG. 1, FIG. 1 illustrates a schematic view of a structure about an OLED display device in accordance with a first embodiment of the present invention.

As shown in FIG. 1, an OLED display device 10 of the present embodiment includes a substrate 12, a colored photo-resist layer 14 and a white OLED 16. Generally, the substrate 12 is made of a transparent material for example, glass. The colored photo-resist layer 14 is disposed on the substrate 12. The colored photo-resist layer 14 includes photo-resist regions 141, 143, and 145. The photo-resist region 141 contains pigment particles 142 for example, red (R) pigment particles therein and further has scattering particles 148 mixed therein. The photo-resist region 143 contains pigment particles 144 for example, green (G) pigment particles therein and further has scattering particles 148 mixed therein. The photo-resist region 145 contains pigment particles 146 for example, blue (B) pigment particles therein and further has scattering particles 148 mixed therein. The pigment particles 142, 144, 146 usually have a grain size in the range of less than 100 nanometers, and can extract light components of desired colors for example, a red light component, a green light component and a blue light component from the white light. In other words, the photo-resist regions 141, 143, and 145 can respectively be red photo-resist region, green photo-resist region, and blue photo-resist region each doped with scattering particles 148.

As described above, the white OLED 16 acts as a white light emitting component/member and is disposed on the colored photo-resist layer 14. The white OLED 16 includes a reflecting electrode 161, a transmitting electrode 165 and an organic white light emitting layer 163. The organic white light emitting layer 163 is for emitting a white light and arranged between the reflecting electrode 161 and the transmitting electrode 165. The reflecting electrode 161 is usually made of a metal and can be a patterned metal layer. The transmitting electrode 165 is made of a transparent conductive material such as indium tin oxide (ITO). The organic white light emitting layer 163 usually includes a group of (i.e. a number of) organic layers for emitting the white light.

In the present embodiment, the photo-resist regions 141, 143, and 145 of the colored photo-resist layer 14 have light scattering property due to the scattering particles 148 mixed therein. The scattering particles 148 can be made of a material which has a refractive index different with that of the pigment particles 142, 144 and 146. The material of the scattering particles 148 is for example, but not limited to, titanium oxide (TiOₓ), silicon oxide (SiO₂), magnesium oxide (MgO), zirconium oxide (ZrOₓ), tin oxide (SnO), beryllium oxide (BeO), zinc sulfide (ZnS), zinc selenide (ZnSe), and the mixture of any two or more of above listed compounds. In the present embodiment, by employing scattering particles having an appropriate refractive index and adjusting the content/amount of the scattering particles, the colored photo-resist layer 14 can achieve a desired haze value for example, greater than 30, such that the light output efficiency of the OLED display device 10 is improved.

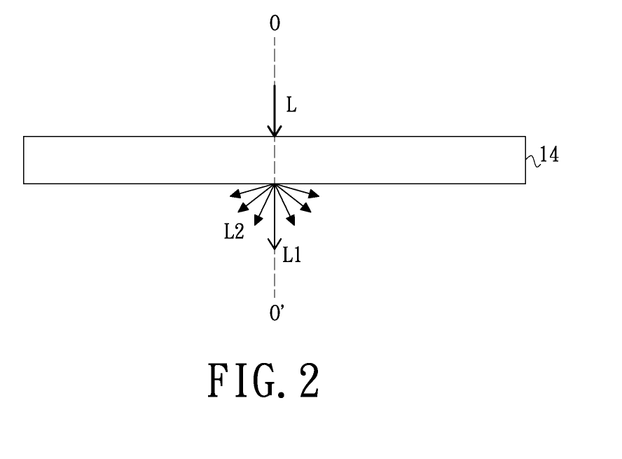

Referring to FIG. 2, the definition of aforementioned haze value is that: when an incident light beam L perpendicularly enters/strikes the colored photo-resist layer 14, i.e., when the incident angel of the incident light beam L (an angle between the incident light beam L and the normal vector oo′) is approximately equal to zero, the flux ratio (i.e., generally light quantity ratio) of the scattering light L2 (i.e. the off-axis transmitting light) to the on-axis transmitting light L1. Herein, the stronger the scattering ability of the colored photo-resist layer 14 is, the greater scattering light flux is obtained, and the haze value of the colored photo-resist layer is increased correspondingly.

It is necessary to note that, the colored photo-resist layer 14 is not limited to only include the three photo-resist regions 141, 143, and 145 as shown in FIG. 1 for a three primary color OLED display device, but also can include much more photo-resist regions for example, four photo-resist regions such as a red photo-resist region, a green photo-resist region, a blue photo-resist region and a white photo-resist region for a multi-primary color OLED display devices so as to achieve a higher display brightness. Generally, the white photo-resist region does not contain any pigment particle therein. Moreover, the white photo-resist region can also be replaced with a yellow photo-resist region or a photo-resist region of other color having a high lightness.

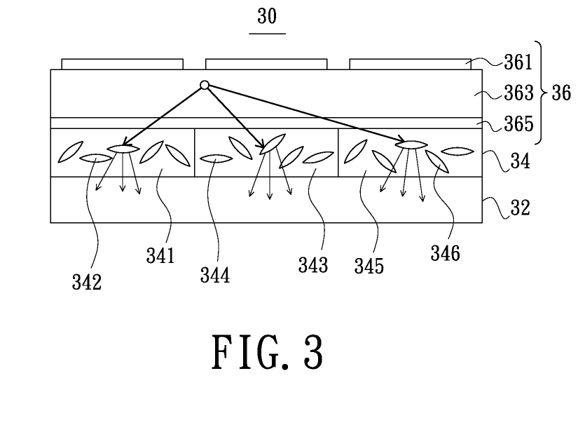

In addition, the embodiment of the present invention is not limited to only utilize the technical means/solution of mixing the scattering particles in the colored photo-resist layer 14 to improve the haze value thereof up to be greater than 30, so as to improve the light output efficiency of the OLED display device, but also can employ other technical means for example, as shown in FIG. 3.

Referring to FIG. 3, FIG. 3 illustrates a schematic view of a structure about an OLED display device in accordance with a second embodiment of the present invention.

As shown in FIG. 3, an OLED display device 30 of the present embodiment includes a substrate 32, a colored photo-resist layer 34 and a white OLED 36. Generally, the substrate 32 is made of a transparent material for example, glass. The colored photo-resist layer 34 is disposed on the substrate 32. The colored photo-resist layer 34 includes photo-resist regions 341, 343, and 345. The photo-resist region 341 contains pigment particles 342 for example, red (R) pigment particles therein. The photo-resist region 343 contains pigment particles 344 for example, green (G) pigment particles therein. The photo-resist region 345 contains pigment particles 346 for example, blue (B) pigment particles therein. The pigment particles 342, 344, 346 can extract light components of desired colors for example, a red light component, a green light component and a blue light component from the white light. In other words, the photo-resist region 341, 343 and 345 can respectively be a red photo-resist region, a green photo-resist region and a blue photo-resist region. Furthermore, in order to give a desired light scattering ability to the colored photo-resist layer 34, in the present embodiment, grain sizes of the pigment particles 342, 344, and 346 are increased to be in the range of greater than 100 nanometers and less than 1000 nanometers, such that the colored photo-resist layer 34 has a desired light scattering ability at the prerequisite of keeping adequate light adsorbing ability. As such, the colored photo-resist layer 34 can achieve an expected haze value for example, greater than 30, such that the light output efficiency of the OLED display device 30 is improved. Certainly, the grain sizes of the pigment particles 342, 344 and 346 can be adjusted according to practical application requirement and such that the grain sizes of only a part of or all the pigment particles 342, 344 and 346 are set to be in the range of greater than 100 nanometers and less than 1000 nanometers.

As described above, the white OLED 36 acts as a white light emitting member and is disposed on colored photo-resist layer 34. The white OLED 36 includes a reflecting electrode 361, a transmitting electrode 365 and an organic white light emitting layer 363. The organic white light emitting layer 363 is for emitting a white light and arranged between the reflecting electrode 361 and the transmitting electrode 365. The reflecting electrode 361 is usually made of metals and can be a patterned metal layer. The transmitting electrode 365 is made of a transparent conductive material such as indium tin oxide (ITO). The organic white light emitting layer 363 usually includes a group of (i.e. a number of) organic layers for emitting the white light.

It is necessary to note that, similarly, the colored photo-resist layer 34 is not limited to only include the three photo-resist regions 341, 343, and 345 as shown in FIG. 3 for a three primary colors OLED display device, but also can include much more of photo-resist regions for example, four photo-resist regions such as a red photo-resist region, a green photo-resist region, a blue photo-resist region and a white photo-resist region for a multi-primary color OLED display device which has a higher brightness. Generally, the white photo-resist region does not contain any pigment particle therein. Moreover, the white photo-resist region can also be replaced with yellow photo-resist region or photo-resist region of other color having high lightness.

As disclosed above, in the foregoing embodiments of the present invention, the colored photo-resist layer uses the scattering effect of the scattering particles mixed into the colored photo-resist layer or at least partly increasing the grain sizes of the pigment particles in the colored photo-resist layer to obtain a desired scattering effect, so that the haze value of the colored photo-resist layer can achieve greater than 30. Accordingly, the OLED display device using the colored photo-resist layer can a relatively higher light output efficiency.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An organic light emitting diode (OLED) display device, comprising:
a substrate;
a colored photo-resist layer, disposed on the substrate; and
a white OLED, disposed on the colored photo-resist layer, wherein the white OLED comprises a reflecting electrode, a transmitting electrode and an organic white light emitting layer, the organic white light emitting layer is for emitting a white light and interposed between the reflecting electrode and the transmitting electrode;
wherein the colored photo-resist at least comprises a first photo-resist region, a second photo-resist region and a third photo-resist region; the first photo-resist region, the second photo-resist region and the third photo-resist region respectively comprises red pigment particles, green pigment particles and blue pigment particles contained therein for extracting red, green, blue light components from the white light;
wherein the colored photo-resist layer achieves a desired haze value by at least utilizing a scattering effect of the red pigment particles, the green pigment particles and the blue pigment particles and/or mixing of scattering particles that are different with the red pigment particles, the green pigment particles and the blue pigment particles into the first photo-resist region, the second photo-resist region and the third photo-resist region.

2. The OLED display device of claim 1, wherein the colored photo-resist layer at least utilizes the mixing of the scattering particles to obtain the desired haze value, the scattering particles is selected from the group consisting of titanium oxide, silicon oxide, magnesium oxide, zirconium oxide, tin oxide, beryllium oxide, zinc sulfide, zinc selenide, and mixtures thereof, a grain size of the scattering particles is less than 1000 nanometers.

3. The OLED display device of claim 1, wherein the colored photo-resist layer at least utilizes the scattering effect of the red pigment particles, the green pigment particles and the blue pigment particles to obtain the desired haze value, grain sizes of the red pigment particles, the green pigment particles and the blue pigment particles are greater than 100 nanometers and less than 1000 nanometers.

4. The OLED display device of claim 1, wherein the transmitting electrode is an indium tin oxide electrode.

5. The OLED display device of claim 1, where the desired haze value of the colored photo-resist layer is greater than 30.

6. An organic light emitting diode (OLED) display device, comprising:
a substrate;
a colored photo-resist layer, disposed on the substrate; and
a white light emitting member, disposed on the colored photo-resist layer, the white light emitting member comprising a metal electrode, a transparent conductive layer and a plurality of organic layers, the organic layers being for emitting a white light and arranged between the metal electrode and the transparent conductive layer;
wherein the colored photo-resist comprises at least three photo-resist regions for respectively extracting light components of three different colors from the white light, and at least some of the three photo-resist regions contains a plurality of pigment particles therein;
wherein the colored photo-resist layer achieves a desired haze value by at least using a scattering effect of the pigment particles and/or mixing of scattering particles that have a refractive index different from another refractive index of the pigment particles into the photo-resist regions.

7. The OLED display device of claim 6, wherein the colored photo-resist layer uses the mixing of the scattering particles to obtain the desired haze value, the scattering particles is selected from the group consisting of titanium oxide, silicon oxide, magnesium oxide, zirconium oxide, tin oxide, beryllium oxide, zinc sulfide, zinc selenide, and mixtures thereof, a grain size of the scattering particles is less than 1000 nanometers.

8. The OLED display device of claim 6, wherein the colored photo-resist layer at least uses the scattering effect of the pigment particles to obtain the desired haze value, a grain size of the pigment particles is greater than 100 nanometers and less than 1000 nanometers.

9. The OLED display device of claim 6, wherein the transparent conductive layer is comprised of indium tin oxide.

10. The OLED display device of claim 6, where the desired haze value of the colored photo-resist layer is greater than 30.
